(19) United States
(12) Patent Application Publication
(10) Pub. No.: US 2012/0104609 A1
(43) Pub. Date: May 3, 2012

(54) DISCRETE CIRCUIT COMPONENT HAVING COPPER BLOCK ELECTRODES AND METHOD OF FABRICATION

(76) Inventor: Chen-Hai Yu, Hsinchu city (TW)

(21) Appl. No.: 12/985,547

(22) Filed: Jan. 6, 2011

Related U.S. Application Data
(60) Provisional application No. 61/408,275, filed on Oct. 29, 2010.

(51) Int. Cl. H01L 23/52; H01L 21/50

(52) U.S. Cl. 257/741; 438/124; 257/E21.499; 257/E23.141

(57) ABSTRACT

A discrete circuit component has copper block electrodes and that utilizes a simple copper substrate as the basis for the component. The component is made by providing an electrode separation hole preformed in the main substrate. The electrode separation hole results in a simple fabrication for the construction of the discrete component product. With the presence of the electrode separation hole, two solid blocks of copper automatically come into shape for each fabricated device at the final phase of production when each device is cut loose from the main production matrix.

### CROSS-REFERENCE TO RELATED APPLICATION

This application claims the benefit of U.S. Provisional Application Ser. No. 61/408,275, filed Oct. 29, 2010, the entire disclosure of which is hereby incorporated herein by reference.

### BACKGROUND

1. Field of the Invention

The present invention relates in general to discrete circuit components and, in particular, to their body package having good electrical and heat dissipation characteristics. More particularly, the present invention relates to such a discrete circuit component package having copper block electrodes and the corresponding method of fabrication.

2. Description of the Related Art

Active and passive discrete circuit components such as transistors, diodes, resistors and capacitors are used in great quantity and variety for the construction of electronic devices. In contrast to an IC, circuit components of the discrete type are available in many different packages, among which the leadless package is one of the most common. The production of many leadless discrete circuit component packages involves the use of printed circuit board technology. Many packages rely on plated through holes for electrical connection between the device dice and the package electrodes.

However, these PCB technology-based discrete circuit component package designs have limitations in both their electrical and thermal performances. The approach to use thick copper plates—as compared to layers of thin copper foil in PCB technology—in the construction of discrete circuit components therefore have been attempted. However, conventional copper substrate-based discrete circuit component productions are complex and involve environmentally unfriendly processes because of their reliance on the etching to shape the copper electrode.

### SUMMARY OF THE INVENTION

It is therefore an object of the present invention to provide a discrete circuit component having copper block electrodes and its corresponding method of fabrication that provides good electrical and thermal characteristics.

It is also an object of the present invention to provide a discrete circuit component having copper block electrodes and its corresponding method of fabrication that aggregates a minimum number of steps of simple, well-proven and matured fabrication technical steps so as to reduce costs and increase reliability.

In order to achieve the above and other objects the present invention provides a discrete circuit component having copper block electrodes and its corresponding method of fabrication that utilizes a simple copper substrate that constitutes the basis for the device. Electrode separation holes preformed in the main initial substrate result in a simple fabrication procedure for the construction of the inventive discrete component products. Literally, with the presence of the electrode separation hole, two solid blocks of copper automatically come into shape for each fabricated device at the final phase of production when each device is cut loose from the main production matrix.

In one preferred embodiment the method of the present invention to make a discrete circuit component that has copper block electrodes comprises first forming an electrode separation hole in a main copper substrate. A circuit dice is then placed on the copper substrate, and the dice has one electrode electrically connected to the copper substrate proximately outside each of a first pair of opposite ends of the electrode separation hole. The dice is then sealed using a hermetic sealing material. Then the sealing material undergoes a cutting procedure that cuts along a peripheral edge of the component to release the component. The cutting cuts inside each of a second pair of opposite ends of the electrode separation hole in the copper substrate that are substantially orthogonal to the first pair of opposite ends.

### BRIEF DESCRIPTION OF THE DRAWINGS

FIG. 1 is a perspective view schematically illustrating a portion of a stamped copper substrate that serves as the basis for the construction of the inventive discrete circuit components of the present invention.

FIG. 2 is a plane view of the substrate of FIG. 1.

FIGS. 3A, 4A, 5 and 6 schematically show the cross sections in different successive stages of the fabrication of the inventive component package using the substrate of FIG. 1.

FIGS. 3B and 4B respectively show the top view of the component package construction on the substrate shown in FIGS. 3A and 4A.

FIG. 7 schematically shows the perspective of a component package in accordance with a preferred embodiment of the present invention.

FIG. 8 schematically shows the cross-sectional construction of another embodiment of the inventive component package.

FIGS. 9 and 10 schematically show the cross-sectional construction of yet another two embodiments of the inventive component package.

FIG. 11 is a plane view of another substrate schematically illustrating a portion of a patterned copper substrate that serves as the basis for the construction of the inventive discrete circuit components of the present invention.

FIG. 12 schematically shows the cross section of the substrate of FIG. 11.

### DETAILED DESCRIPTION OF THE PREFERRED EMBODIMENTS

In order to achieve superior electrical and thermal characteristics, the inventive discrete circuit component utilizes an entire sheet of copper substrate as the basis for the construction of the component package. According to a preferred embodiment of the present invention, the construction of, for example, a transient voltage suppressor (TVS) diode to the JEDEC 0201 device dimensioning standard, may be initiated on a sheet of copper plate with a typical thickness of 0.12 mm.

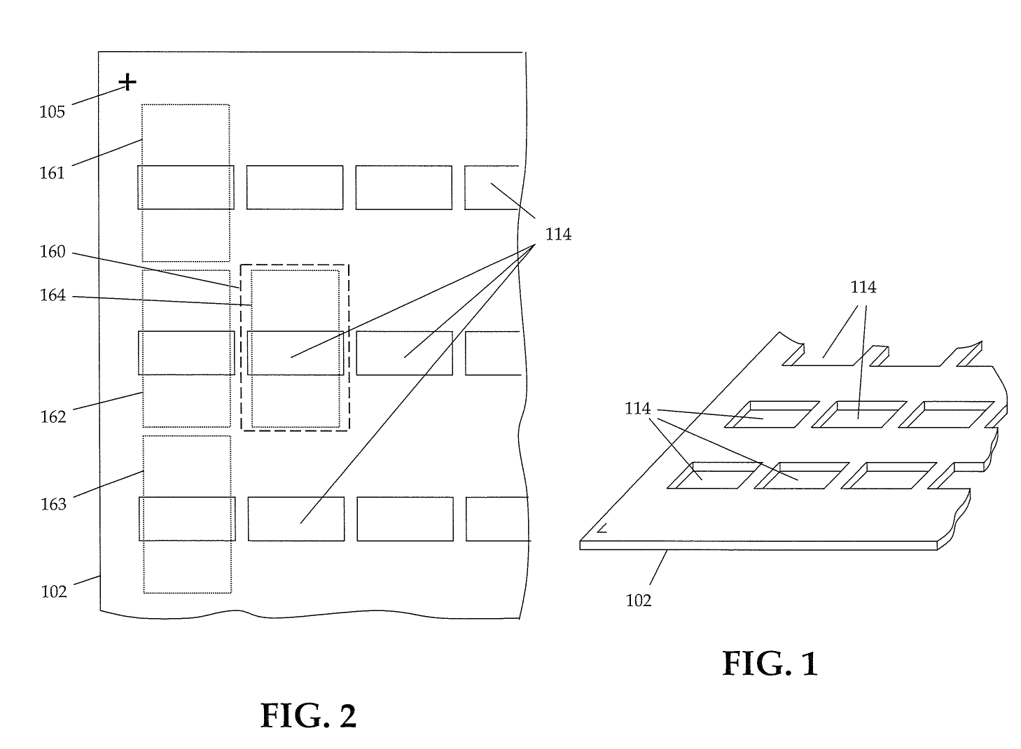

As will be described in the following paragraphs making reference to the accompanying drawings, essentially the entire thickness of this device substrate is utilized as the device electrode, thereby ensuring good electrical and thermal characteristics of the fabricated device. FIG. 1 is a perspective view schematically illustrating a portion of a stamped copper substrate that serves as the basis for the construction of the inventive discrete circuit components of the present invention. FIG. 2 is a plan view of the substrate of FIG. 1.

As shown in the drawing, the construction of the inventive circuit component package starts with the preparation of a copper plate 102 that has holes, a production phase feature referred to as the electrode separation holes 114 at this stage of fabrication. These holes 114, as shown, are formed preferably in a stamping procedure and line up in a two-dimensional matrix that achieves maximized device population density on the substrate 102.

For example, unit areas identified in FIG. 1 by fine dotted lines 161, 162, 163 and 164—for each of which the “real estate” of one individual discrete component is assigned to on the substrate 102—are orderly lined up in the two-dimensional array that has, for example, package units 161, 162 and 163 (along with others not identified) in the same vertical column and units 162 and 164 (also along with others) in the same horizontal row.

All these rows and columns of device packages' assigned unit areas can populate the maximum possible surface of the copper substrate 102. For example, to be compatible with and take advantage of modern printed circuit board manufacturing facilities, a suitable size of substrate 102 may, for example, be of a size of some 60 mm×40 mm. With this substrate size, some 2,000 packages of discrete circuit component of the size 0.4 mm×0.2 mm can be produced on just one single substrate—a commercially economic and efficient way of mass production.

It should be noted, as shown in FIG. 1, that there is one hole 114 per unit area of every fabricated package. Also note that the hole 114 is preferably in an elongated rectangular shape that traverses the longitudinal direction of each of the package unit area's real estate. Preferably, the hole 114 is substantially at the center of its unit area. One essential characteristic of each hole 114 is, as shown in FIG. 1, that its longitudinal length must extend across and beyond the width of the each component real estate. This is to ensure that the two electrodes for each package unit can be automatically disconnected from each other electrically as it is cut out of the entire fabrication substrate 102, as will be shown in the following descriptive paragraphs.

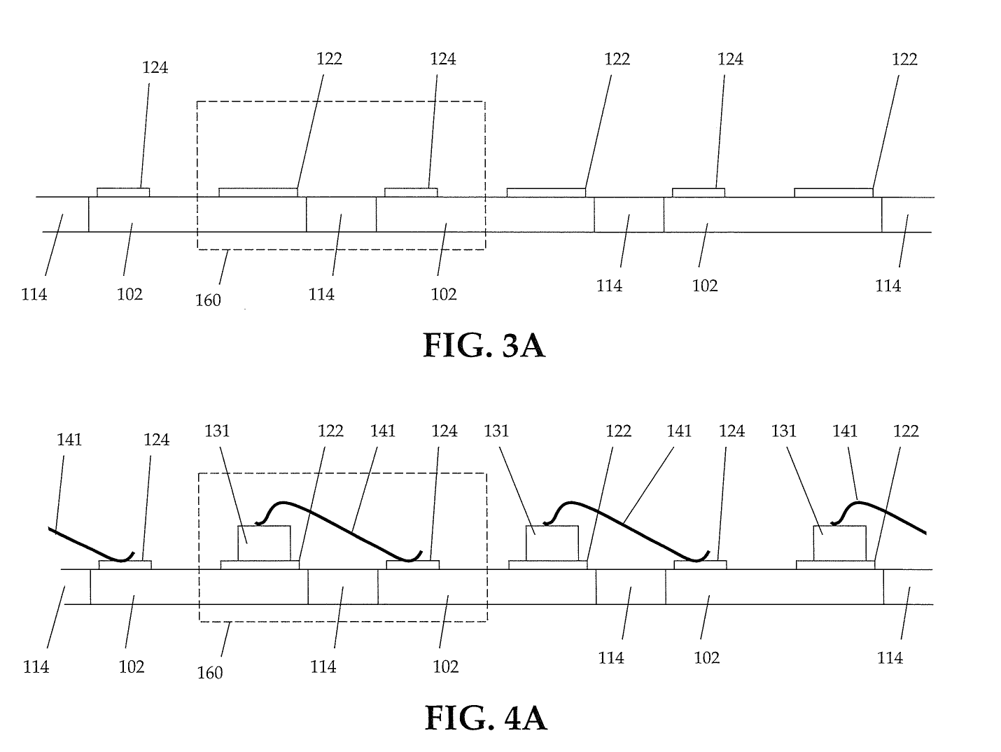

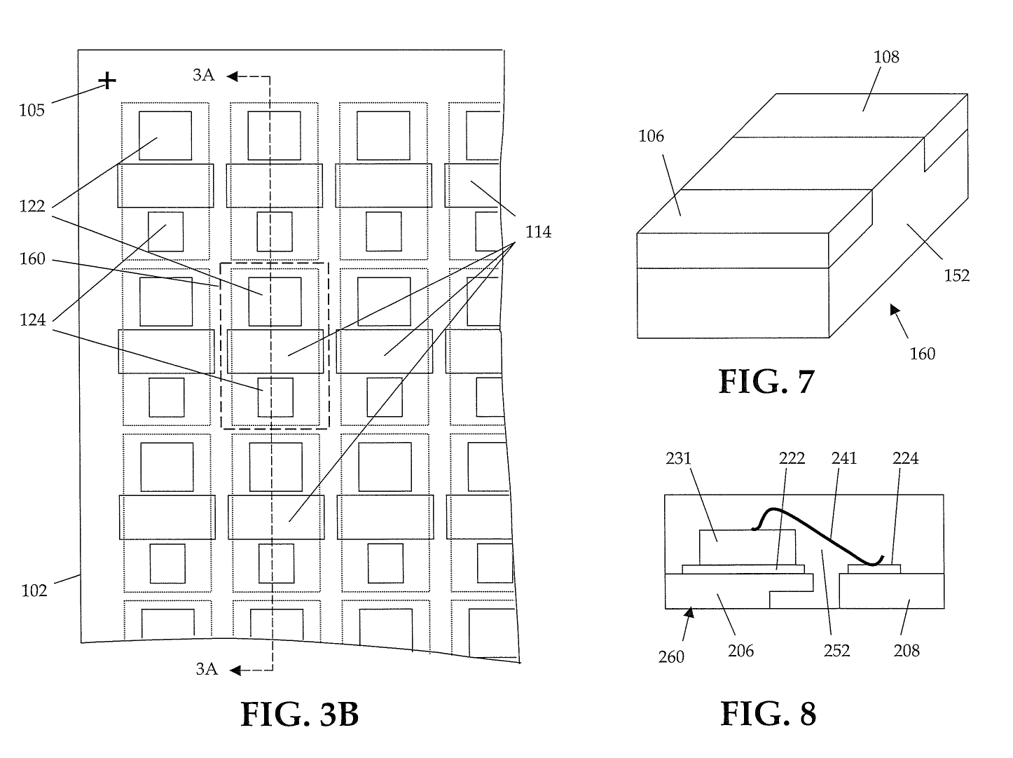

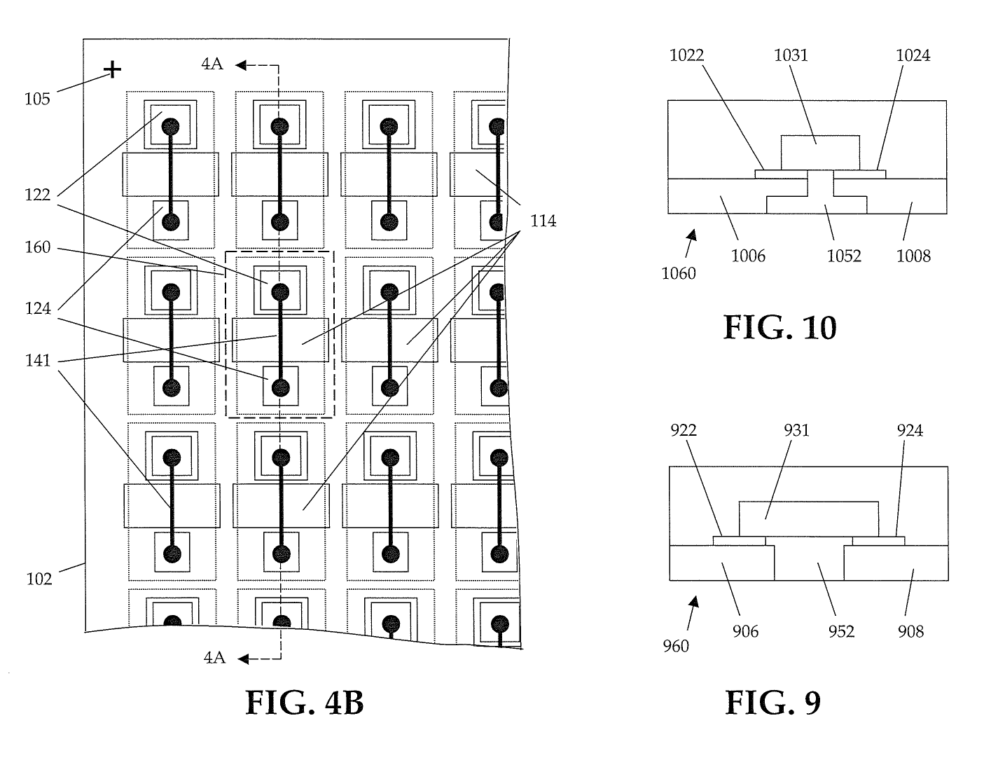

FIGS. 3A, 4A, 5 and 6 schematically show the cross sections in different successive stages of the fabrication of the inventive component package using the substrate of FIG. 1. FIGS. 3B and 4B respectively show the top view of the component package construction on the substrate shown in FIGS. 3A and 4A. At the fabrication stage shown in FIGS. 3A and 3B, the substrate 102 first has each of its device package unit areas acquire a pair of solder pads 122 and 124. Note that the cross-sectional view in FIG. 3A is taken along the line 3A-3A shown in the top view of FIG. 3B and, similarly, view in FIG. 4A is along line 4A-4A in FIG. 4B.

Pads 122 and 124 can be formed on the surface of the copper substrate 102 using, for example, simple and low-cost screen printing technique commonly used in PCB fabrication that screen-prints, for example, silver-containing solder paste.

In the depicted example of FIGS. 3A and 3B, the pads 122 and 124 may have different sizes. Preferably, pad 122 should have a size large enough to properly physically and electrically secure the device dice thereon, be it a diode or any other. By contrast, the other pad 124 can be much smaller in size since it is used only to receive the bonding of the end of a piece of bonding wire, as is clearly illustrated in FIGS. 4A and 4B.

Though, as would be readily understood, before the bonding wires 141 can be installed, one circuit dice 131 should be in place on each of the pad 122 on the entire substrate 102. This can be done using a conventional robotic pick-and-place technique seen daily in the manufacture of electronic circuit boards.

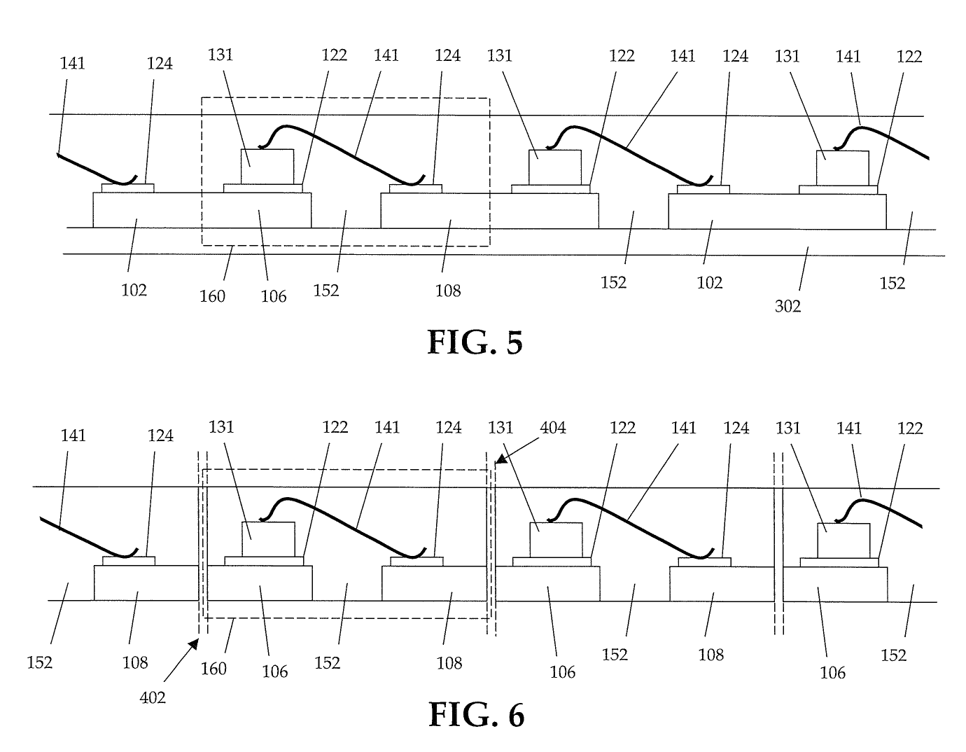

Then, as illustrated in the cross-sectional view of FIG. 5, a supportive and hole-blocking fixture 302 in the form of a plate with a size compatible with the copper substrate 102 is placed under the substrate, as is illustrated in the drawing. Together with the use of a top mold not shown, this permits the injection of a sealing epoxy 152 so that all dices 131 and bonding wires 141 already installed on their corresponding pads 122 and 124 can be hermetically sealed.

Note that at this stage (of FIG. 5) an entire matrix of hundreds or more of circuit dices are molded into one single piece, with one device unit identified by the phantom line box indicated by reference numeral 160.

Then, in FIG. 6, each of the sealed circuit component units 160 can be separated from the mass matrix using means such as mechanical cutting or laser burn-cutting. The separation cut can be implemented along the pre-designated cutting paths such as cutting paths 402 and 404 across the longitudinal axis of the device units 160 illustrated in FIG. 6 and cutting paths along the device longitudinal axis not shown.

FIG. 7 schematically shows the perspective of a component package in accordance with a preferred embodiment of the present invention such as that described in FIGS. 1-6. The illustrated device bottom view reveals the electrodes 106 and 108 in the form of entire blocks of copper that ensure good electrical and thermal characteristics for the device 160.

FIG. 8 schematically shows the cross-sectional construction of another embodiment of the inventive component package. The component 260 can be fabricated using essentially the same method described above, with the exception that the very first copper substrate stamping procedure is a little bit different. Essentially, the stamping of the copper substrate forms a narrower separation between the two electrodes 206 and 208 in the surface that is used to bear the device dice 231. This allows the formation of a larger pad 222 that can accommodate a larger device dice 231 for the requirement of, for example, a larger power rating.

FIGS. 9 and 10 schematically show the cross-sectional construction of yet another two embodiments of the inventive component package. These packages 960 and 1060 use no wire-bonding for the electrical connection of the electrodes at the bottom of the device dices 931 and 1031 to that, 906, 908 and 1006, 1008 respectively of the packages. Instead, as would be readily understood by those skilled in the art, the device dice is placed directly on the substrate, with its electrodes soldered to each of the substrate electrodes. The difference between the packages 960 and 1060 is that a smaller electrode separation is found in 1060 to accommodate for the smaller device dice.

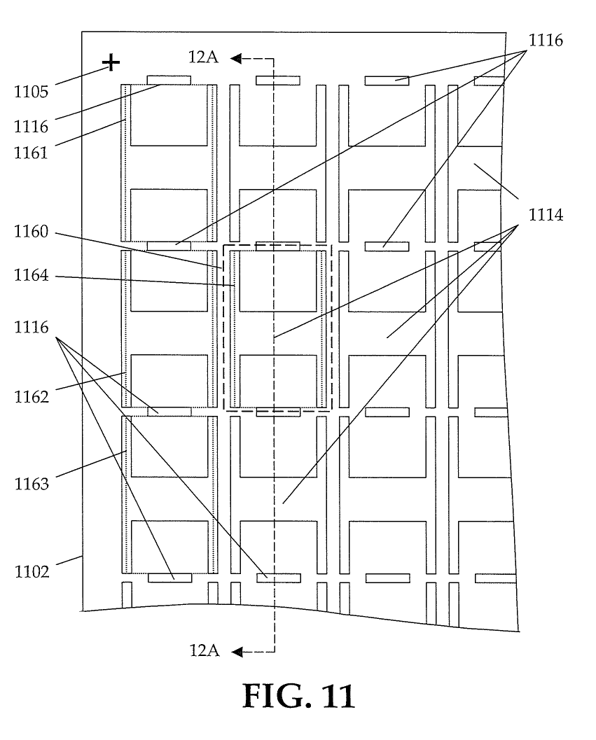

FIG. 11 is a plan view of another substrate schematically illustrating a portion of a patterned copper substrate 1102 that serves as the basis for the construction of the inventive discrete circuit components of the present invention. Similar as in the case of FIG. 2, the hole-patterned substrate 1102 serves as the basis for the construction of the inventive circuit component packages. Each hole 1114 is a production phase feature, the electrode separation hole. Instead of a simple horizontal rectangular hole 114 in FIG. 2, hole 1114 has a contour resembling the letter “H.”

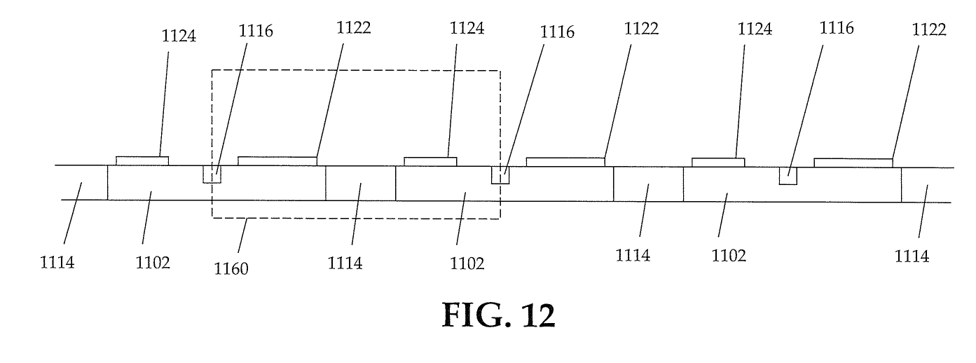

Essentially, four narrow vertical slots are formed at the four corners of each basic rectangular hole of each H-shaped hole 1114. Additionally, two horizontal slots or depressions 1116 are formed at the center top and bottom of each H-shaped hole 1114. FIG. 12 schematically shows the cross section of the substrate of FIG. 11 taken along the 12A-12A line in FIG. 11.

Compared to the case of the substrate 102 of FIGS. 1 and 2, individual discrete components fabricated on substrate 1102 are more readily separated from each other because at least three sides of each of their two copper-block electrodes are pre-cut. With a through-slot or a thickness-reduced depression, the fourth side (at the longitudinal ends of each component) is easily cut open. This allows for reduced mechanical stress induced to each fabricated component when it is subject to the cut-loose procedure, particularly when using a mechanical cutting procedure.

Again, holes 1114 and slots/depressions 1116 can be formed in a mechanical stamping procedure, although a copper etching procedure well known in the art is also applicable. Note that these slots/depressions 1116 shown in FIG. 12 are non-penetrating recesses.

Good electrical and thermal characteristics attributable to the inventive package design of the present invention translate directly into a large device current, and a high device voltage for a discrete diode component as small as 0.2 mm×0.1 mm, as well as good heat dissipation from the device. All these desirable performance characteristics are the result of the device electrodes in the form of an entire copper block.

Also, the fabrication of the inventive discrete circuit component packages involves an aggregation of a minimum number of steps of simple, well-proven and matured fabrication technical steps. There are no bottle-neck processes such as electrically conductive plated through-hole making and/or their plugging to increase overall production costs.

One important aspect about this inventive discrete circuit component package design is the use of a simple copper substrate that constitutes the basis for the device. In its entirety at the initial stage, the substrate serves as the rigid carrier of device dices that ferries the packages through the entire fabrication process. At the last phase of fabrication, the entire plate of copper substrate is cut for each device and becomes the rigid and robust electrodes for each.

Thus, the electrode separation hole preformed in the main substrate is the key to the simple nature of the fabrication procedure used for the construction of the product. Literally, with the presence of the hole, two solid blocks of copper electrode automatically come into shape for each fabricated device at the final phase of production when each device is cut loose from the main production matrix.

More important, no environmentally-unfriendly metal etching process is needed. Experimental prototype diode devices have been made that demonstrate good electrical and thermal specifications far exceeding equivalent devices of the conventional design. A reason for this superior electrical and thermal performance is simple—due to the use of entire blocks of copper as device electrodes with the device dice sitting directly on one of the blocks.

While the above is a full description of the specific embodiments of the present invention, various modifications, alternative constructions and equivalents may be used. Therefore, the above description and illustrations should not be taken as limiting the scope of the present invention.

What is claimed is:

1. A method for making a discrete circuit component having copper block electrodes comprising:
forming an electrode separation hole in a main copper substrate;
placing a circuit dice on said copper substrate, said dice having one electrode electrically connected to said copper substrate proximately outside each of a first pair of opposite ends of said electrode separation hole;
sealing said dice using a hermetical sealing material;
cutting said sealing material along a peripheral edge of said component to release said component wherein said cutting cuts inside each of a second pair of opposite ends of said electrode separation hole in said copper substrate that are substantially orthogonal to said first pair of opposite ends.

2. The method of claim 1 wherein said electrode separation hole in said copper substrate having an extension slot extending along a direction parallel to the edges of said second pair of opposite ends outwardly away from said hole at each of the junctions where said first and second pairs of opposite ends meet, said electrode separation hole thereby has the shape of a letter H.

3. The method of claim 1 further comprising forming at least one slot at said peripheral edge of said component parallel to said edges of said first pair of opposite ends of said electrode separation hole.

4. The method of claim 3 wherein said slot is a penetrating slot.

5. The method of claim 3 wherein said slot is a copper substrate thickness-reducing slot.

6. The method of claim 1 wherein said circuit dice is the dice of a diode.

7. The method of claim 1 wherein at least one electrode of said circuit dice is connected to said copper substrate using wire bonding.

8. The method of claim 1 wherein all electrodes of said circuit dice is soldered directly onto said copper substrate.

9. A discrete circuit component fabricated using the method of claim 1.
